(19) United States
(12) Patent Application Publication
(10) Pub. No.: US 2026/0245839 A1
(43) Pub. Date: Aug. 20, 2026

(54) SUBSTRATE PROCESSING APPARATUS AND COOLING METHOD

(71) Applicant: Tokyo Electron Limited, Tokyo (JP)

(72) Inventor: Satoshi TAGA, Miyagi (JP)

(73) Assignee: Tokyo Electron Limited, Tokyo (JP)

(21) Appl. No.: 19/568,339

(22) Filed: Mar. 16, 2026

Related U.S. Application Data
(63) Continuation of application No. PCT/JP2024/029501, filed on Aug. 20, 2024.

(30) Foreign Application Priority Data
Sep. 29, 2023 (JP) 2023-169467

(51) Int. Cl. H01J 37/32

(52) U.S. Cl. CPC H01J 37/32724; H01J 37/32522; H01J 37/32532

(57) ABSTRACT

A substrate processing apparatus includes a member, a cooler, and a controller. The member includes a channel inside. The channel has an inlet and an outlet. The cooler cools the member. The cooler includes a mist generator connected to the inlet of the channel to generate a mist of a coolant, a cool air supply connected to the inlet of the channel, and a vacuum pump connected to the outlet of the channel. The controller controls the cooler to cause the cooler to repeatedly perform processing including (a) supplying the mist from the mist generator to the channel that is under a pressure reduced by the vacuum pump, (b) supplying cool air from the cool air supply to the channel, and (c) evacuating the channel with the vacuum pump.

### CROSS-REFERENCE TO RELATED APPLICATIONS

This application is a continuation application of PCT Application No. PCT/JP 2024/029501, filed on Aug. 20, 2024, which claims the benefit of priority from Japanese Patent Application No. 2023-169467, filed on Sep. 29, 2023. The entire contents of the above listed PCT and priority applications are incorporated herein by reference.

### FIELD

Exemplary embodiments of the present disclosure relate to a substrate processing apparatus and a cooling method.

### BACKGROUND

A semiconductor manufacturing apparatus performs processing of substrates. Patent Literature 1 below describes a technique for supplying a mist to a channel in a chamber to cool the chamber with vaporization heat of the mist.

### CITATION LIST

### Patent Literature

Patent Literature 1: Japanese Unexamined Patent Application Publication No. 2005-197600

### BRIEF SUMMARY

### Technical Problem

One or more aspects of the present disclosure are directed to a technique for effectively cooling a member in a substrate processing apparatus.

### Solution to Problem

A substrate processing apparatus according to one exemplary embodiment includes a member, a cooler, and a controller. The member includes a channel inside. The channel has an inlet and an outlet. The cooler cools the member. The cooler includes a mist generator connected to the inlet of the channel to generate a mist of a coolant, a cool air supply connected to the inlet of the channel, and a vacuum pump connected to the outlet of the channel. The controller controls the cooler to cause the cooler to repeatedly perform processing including (a) supplying the mist from the mist generator to the channel that is under a pressure reduced by the vacuum pump, (b) supplying cool air from the cool air supply to the channel, and (c) evacuating the channel with the vacuum pump.

### Advantageous Effects

The technique according to one exemplary embodiment efficiently cools the member in the substrate processing apparatus.

### BRIEF DESCRIPTION OF DRAWINGS

FIG. 1 is a diagram of a plasma processing system, illustrating an example structure.

FIG. 2 is a diagram of a capacitively coupled plasma processing apparatus, illustrating an example structure.

FIG. 3 is a diagram of a cooler in one exemplary embodiment.

FIG. 4 is a diagram of an example mist generator usable in the cooler in the exemplary embodiment.

FIG. 5 is a flowchart of a cooling method according to the exemplary embodiment.

FIG. 6 is a timing chart of a pressure in a channel controlled with the cooling method according to the exemplary embodiment.

FIGS. 7A to 7D are tables each showing example states of valves and pumps controlled with the cooling method according to the exemplary embodiment.

FIGS. 8A to 8D are tables each showing example states of the valves and the pumps controlled with the cooling method according to the exemplary embodiment.

FIGS. 9A to 9D are tables each showing example states of the valves and the pumps controlled with the cooling method according to the exemplary embodiment.

FIGS. 10A to 10D are tables each showing example states of the valves and the pumps controlled with the cooling method according to the exemplary embodiment.

FIGS. 11A to 11G are diagrams each showing an example channel in a base in the exemplary embodiment.

FIG. 12 is a diagram of a plasma processing apparatus according to a modification of the exemplary embodiment.

### DETAILED DESCRIPTION

Various exemplary embodiments will be described in detail below with reference to the drawings. In the figures, like reference numerals denote like or corresponding components.

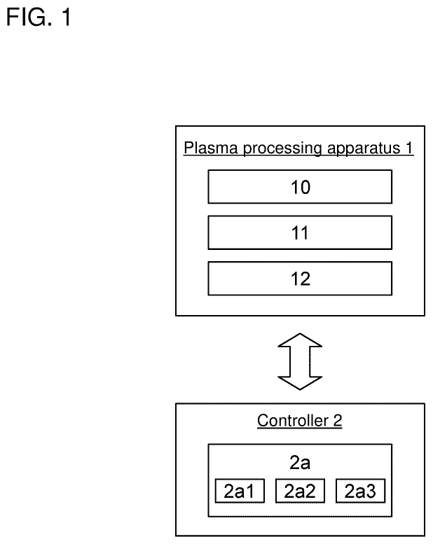

FIG. 1 is a diagram of a plasma processing system, illustrating an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas inlet for supplying at least one processing gas into the plasma processing space and at least one gas outlet for exhausting the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates a plasma from at least one processing gas supplied into the plasma processing space. The plasma generated in the plasma processing space may be, for example, a capacitively coupled plasma (CCP), an inductively coupled plasma (ICP), an electron cyclotron resonance (ECR) plasma, a helicon wave plasma (HWP), or a surface wave plasma (SWP). The plasma generator 12 may be one of various plasma generators including an alternating current (AC) plasma generator and a direct current (DC) plasma generator. In one embodiment, an AC signal (AC power) used in the AC plasma generator has a frequency in a range of 100 kHz to 10 GHz. Thus, the AC signal may be a radio-frequency (RF) signal or a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the present disclosure. The controller 2 may cause the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2al may perform various control operations by loading programs from the storage 2a2 and executing the loaded programs. The programs may be prestored in the storage 2a2 or may be obtained through a medium as appropriate. The obtained programs are stored into the storage 2a2 to be loaded from the storage 2a2 and executed by the processor 2a1. The medium may be one of various storage media readable by the computer 2a or a communication line connected to the communication interface 2a3. The processor 2al may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

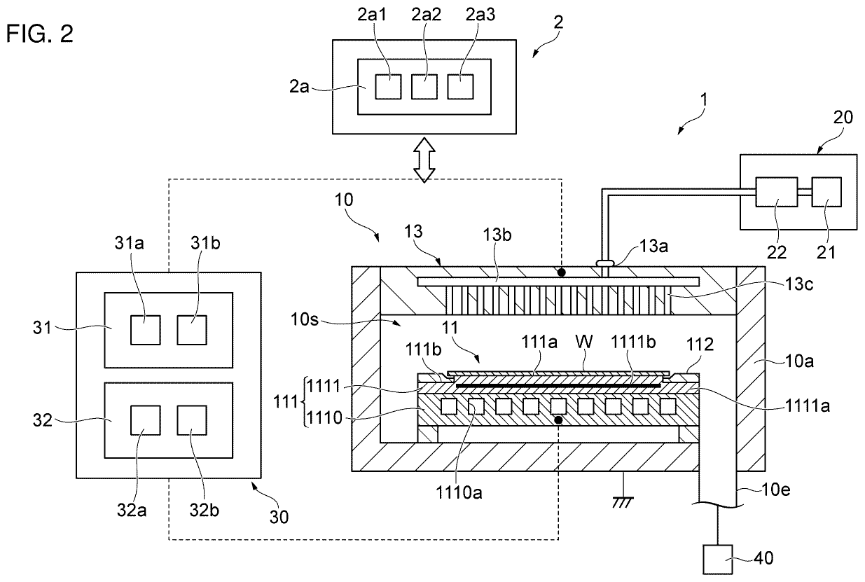

An example structure of a capacitively coupled plasma processing apparatus as an example of the plasma processing apparatus 1 will now be described. FIG. 2 is a diagram of the capacitively coupled plasma processing apparatus, illustrating an example structure.

The capacitively coupled plasma processing apparatus 1 includes the plasma processing chamber 10, the gas supply 20, a power supply 30, and the exhaust system 40. The plasma processing apparatus 1 further includes the substrate support 11 and a gas guide unit. The gas guide unit allows at least one processing gas to be introduced into the plasma processing chamber 10. The gas guide unit includes a showerhead 13. The substrate support 11 is located in the plasma processing chamber 10. The showerhead 13 is located above the substrate support 11. In one embodiment, the showerhead 13 defines at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF/DC electrode coupled to an RF power supply 31 or a DC power supply 32, or both (described later) may be located inside the ceramic member 1111a. In this case, the RF/DC electrode functions as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may function as multiple lower electrodes. The electrostatic electrode 1111b may also function as a lower electrode. The substrate support 11 thus includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The showerhead 13 introduces at least one processing gas from the gas supply 20 into the plasma processing space 10s. The showerhead 13 includes at least one gas inlet 13a, at least one gas-diffusion compartment 13b, and multiple gas guides 13c. The processing gas supplied to the gas inlet 13a passes through the gas-diffusion compartment 13b and is introduced into the plasma processing space 10s through the gas guides 13c. The showerhead 13 further includes at least one upper electrode. In addition to the showerhead 13, the gas guide unit may include one or more side gas injectors (SGIs) installed in one or more openings in the sidewall 10a.

The gas supply 20 may include at least one gas source 21 and at least one flow controller 22. In one embodiment, the gas supply 20 supplies at least one processing gas from each gas source 21 to the showerhead 13 through the corresponding flow controller 22. The flow controller 22 may be, for example, a mass flow controller or a pressure-based flow controller. The gas supply 20 may further include at least one flow rate modulator that causes at least one processing gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This generates a plasma from at least one processing gas supplied into the plasma processing space 10s. The RF power supply 31 may thus function as at least a part of the plasma generator 12. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 31a may generate multiple source RF signals with different frequencies. The one or more generated source RF signals are provided to at least one lower electrode or at least one upper electrode, or both.

The second RF generator 31b is coupled to at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode to generate a first DC signal. The generated first DC signal is applied to at least one lower electrode. In one embodiment, the second DC generator 32b is coupled to at least one upper electrode to generate a second DC signal. The generated second DC signal is applied to at least one upper electrode.

In various embodiments, the first DC signal and the second DC signal may be pulsed. In this case, the sequence of voltage pulses is applied to at least one lower electrode or at least one upper electrode, or both. The voltage pulses may have rectangular, trapezoidal, or triangular pulse waveforms, or a combination of these. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31 or may include the first DC generator 32a in place of the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

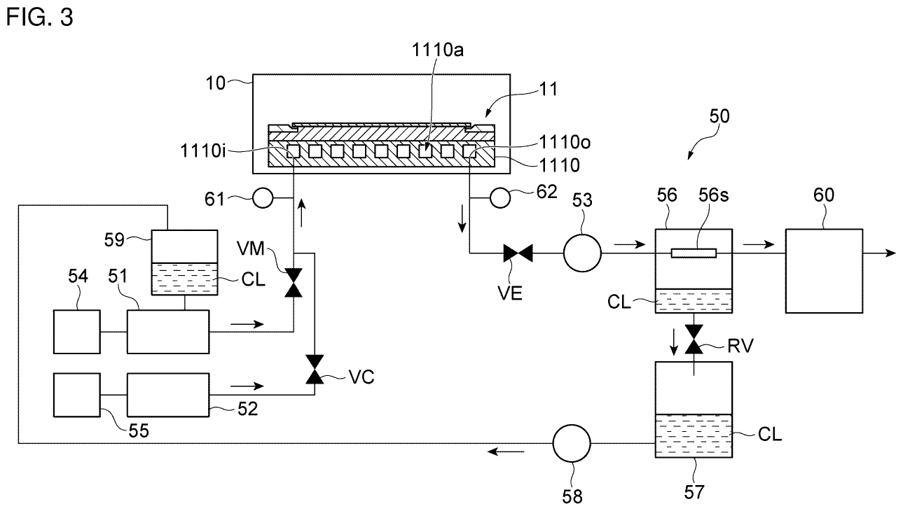

A cooler in the substrate processing apparatus in one exemplary embodiment will now be described with reference to FIG. 3. FIG. 3 is a diagram of the cooler in the exemplary embodiment. A cooler 50 shown in FIG. 3 cools a member including a channel in the substrate processing apparatus. In the example shown in FIG. 3, the cooler 50 cools the substrate support 11, or more specifically, the base 1110. The cooler 50 includes a mist generator 51, a cool air supply 52, and a vacuum pump 53. The cooler 50 may further include a carrier gas supply 54.

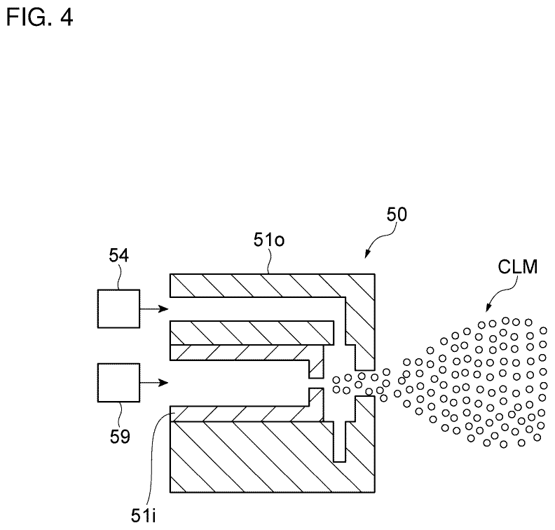

The mist generator 51 generates a mist CLM (refer to FIG. 4) of a coolant CL. The mist generator 51 may generate the mist CLM of the coolant CL from a reservoir 59 (described later). The coolant CL may include water, alcohol, ammonia, or a fluorine liquid. The water may include pure water, city water, or city water and an additive such as a rust inhibitor. The alcohol may be, for example, an ethylene glycol solution. The fluorine liquid may include a fluorine inert liquid or a perfluoropolyether fluorine fluid.

The mist generator 51 is connected to an inlet 1110i of the channel 1110a in the substrate support 11. The mist generator 51 may be connected to the inlet 1110i with a valve VM. The mist CLM generated by the mist generator 51 may be supplied to the channel 1110a together with a carrier gas supplied from the carrier gas supply 54. The carrier gas is, for example, dry air.

FIG. 4 is a diagram of an example mist generator usable in the cooler in the exemplary embodiment. In one embodiment, the mist generator 51 may be a mist generator with a spray nozzle for splaying as shown in FIG. 4. In the embodiment in FIG. 4, the mist generator 51 includes an inner nozzle 51i and an outer nozzle 510. The inner nozzle 51i ejects, through its orifice, the mist CLM of the coolant CL under a pressure. The outer nozzle 510 defines a channel for the carrier gas on the outer periphery of the inner nozzle 51i. The outer nozzle 510 has an orifice in front of the orifice in the inner nozzle 51i. The channel in the outer nozzle 510 extends to the front of the orifice in the inner nozzle 51i and connects to the orifice in the outer nozzle 510. The mist generator 51 shown in FIG. 4 allows the mist CLM ejected through the orifice in the inner nozzle 51i to be ejected through the orifice in the outer nozzle 510 together with the carrier gas and supplied to the channel 1110a.

Referring back to FIG. 3, the cool air supply 52 is connected to the inlet 1110i of the channel 1110a. The cool air supply 52 may be connected to the inlet 1110i with a valve VC. The cool air supply 52 generates cool air from air supplied from the air supply 55 and supplies the cool air to the channel 1110a. The air supplied from the air supply 55 is, for example, dry air. The cool air supply 52 may be, for example, an air cooler. The cooler 50 may further include a pressure sensor 61. The pressure sensor 61 measures a pressure in a pipe connecting the inlet 1110i and each of the mist generator 51 and the cool air supply 52.

The vacuum pump 53 is connected to an outlet 11100 of the channel 1110a. The vacuum pump 53 may be connected to the outlet 11100 with a valve VE. The vacuum pump 53 exhausts a gas in the channel 1110a and the coolant CL (or a gas of the coolant CL) from the channel 1110a. The vacuum pump 53 may be, for example, a liquid ring pump. The cooler 50 may further include a pressure sensor 62. The pressure sensor 62 measures a pressure in a pipe connecting the vacuum pump 53 and the outlet 11100.

The cooler 50 thus facilitates condensation of the mist CLM in the channel 1110a (adsorption onto a surface defining the channel 1110a) with the cool air supplied from the cool air supply 52. The vacuum pump 53 reduces the pressure in the channel 1110a (or evacuates the channel 1110a) to facilitate vaporization of the coolant CL condensed in the channel 1110a. Thus, the cooler 50 effectively cools the substrate support 11 or the base 1110. The channel 1110a receives no heat-exchange medium under a pressure. The cooler 50 thus reduces expansion of the substrate support 11 (or the base 1110).

In one embodiment, the cooler 50 may further include a trap 56 and a collector. The trap 56 is connected to the outlet 11100 with the vacuum pump 53 between the trap 56 and the outlet 11100. The trap 56 includes a tank. The trap 56 receives, in the tank, a mixture of the gas from the vacuum pump 53 and the coolant CL (or the gas of the coolant CL). The trap 56 includes a separator 56s that separates the gas from the coolant CL. The gas separated by the separator 56s is exhausted outside through a filter 60. The coolant CL separated by the separator 56s is stored into the tank in the trap 56.

The collector collects and stores the coolant CL and is connected between the trap 56 and the mist generator 51. In one embodiment, the collector may include a receiver 57, a liquid circulation pump 58, and the reservoir 59. The receiver 57 includes a tank for storing the coolant CL and is connected between the trap 56 and the liquid circulation pump 58. The tank in the receiver 57 may be connected to the tank in the trap 56 with a valve RV. The reservoir 59 includes another tank for storing the coolant CL and is connected between the liquid circulation pump 58 and the mist generator 51. The collector allows, by activating the liquid circulation pump 58, the coolant CL in the tank in the trap 56 to be returned to the tank in the reservoir 59 through the tank in the receiver 57 and the liquid circulation pump 58. The coolant CL returned to the reservoir 59 is reused in the mist generator 51.

In one embodiment, the controller 2 may adjust one or more of multiple control parameters for controlling the temperature of the member, such as the substrate support 11, with the cooler 50. The control parameters include an amount of the mist CLM generated by the mist generator 51, the temperature of the mist CLM, the duration for which the mist CLM is supplied to the channel 1110a, the flow rate of the carrier gas, the flow rate of the cool air supplied from the cool air supply 52, the temperature of the cool air, the duration for which the cool air is supplied, and the pumping speed of the vacuum pump 53. The control parameters may further include the duration for which the valve VE is open or closed, or both, the duration for which the supply of the mist CLM is stopped, and the duration for which the supply of the cool air is stopped.

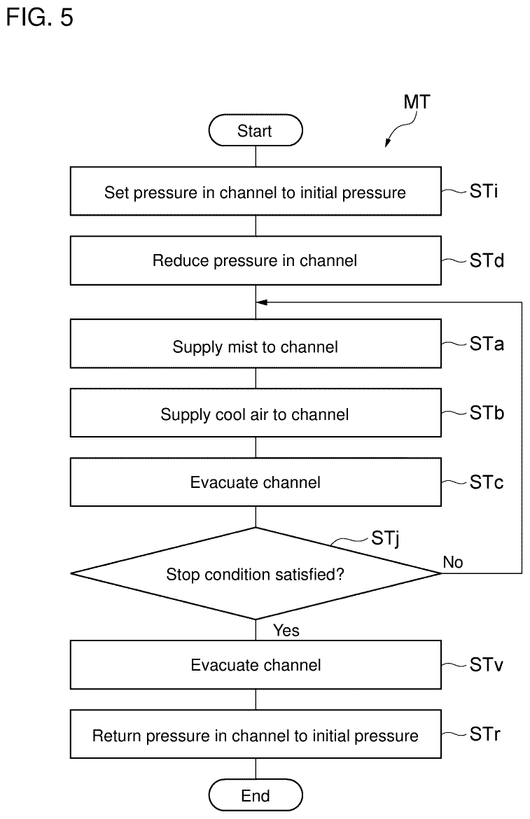

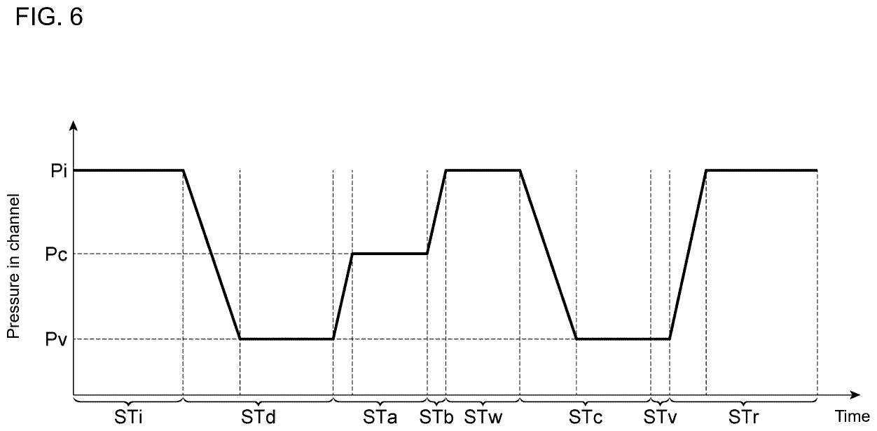

A cooling method according to one exemplary embodiment will now be described with reference to FIGS. 5 and 6. FIG. 5 is a flowchart of the cooling method according to the exemplary embodiment. FIG. 6 is a timing chart of a pressure in the channel controlled with the cooling method according to the exemplary embodiment. In each step of the cooling method shown in FIG. 5 (hereafter referred to as a method MT), the components of the cooler 50 may be controlled by the controller 2.

The cooling method shown in FIG. 5 (hereafter referred to as the method MT) starts in step STi. In step STi, the pressure in the channel 1110a is set to an initial pressure Pi (refer to FIG. 6). The initial pressure Pi is, for example, an atmospheric pressure.

In subsequent step STd, the vacuum pump 53 reduces the pressure in the channel 1110a. As shown in FIG. 5, the pressure in the channel 1110a is reduced to reach a first pressure Pv in step STd. The first pressure Pv may be a minimum pressure achievable with the vacuum pump 53. After the pressure in the channel 1110a reaches the first pressure Pv in step STd, the pressure in the channel 1110a may be maintained at the first pressure Pv for a specified time.

In subsequent step STa, the mist generator 51 supplies the mist CLM of the coolant CL to the channel 1110a that is under a pressure reduced by the vacuum pump 53. The mist CLM is supplied together with the carrier gas from the carrier gas supply 54. The mist CLM is supplied in step STa to cause the pressure in the channel 1110a to reach a second pressure Pc. The second pressure Pc is higher than the first pressure Pv. After the pressure in the channel 1110a reaches the second pressure Pc in step STa, a standby state may continue for a specified time.

In subsequent step STb, the cool air supply 52 supplies cool air to the channel 1110a. In step STb, the cool air from the cool air supply 52 facilitates condensation of the mist CLM in the channel 1110a (adsorption onto the surface defining the channel 1110a).

The method MT may further include subsequent step STw. After the supply of the cool air in step STb is stopped, a standby state continues for a specified time in step STw. In step STw, condensation of the mist CLM in the channel 1110a (adsorption onto the surface defining the channel 1110a) proceeds.

In subsequent step STc, the vacuum pump 53 reduces the pressure in the channel 1110a. In step STc, the vacuum pump 53 may evacuate the channel 1110a. This vaporizes the coolant CL in the channel 1110a and cools the substrate support 11 (or the base 1110) with vaporization heat. In step STc, the pressure in the channel 1110a may be reduced to reach the first pressure Pv. After the pressure in the channel 1110a reaches the first pressure Pv in step STc, the pressure in the channel 1110a may be maintained at the first pressure Pv for a specified time. The pressure in the channel 1110a may reach another pressure different from the first pressure Pv in step STc.

The method MT may include a cycle including steps STa to STc performed repeatedly. In step STj, the determination is performed as to whether a stop condition is satisfied. The stop condition is satisfied when the cycle is repeated a predetermined number of times or when the cycle is repeated for a predetermined duration. When the stop condition is determined not to be satisfied in step STj, the cycle is restarted. When the stop condition is determined to be satisfied in step STj, the processing advances to step STv.

In step STv, the vacuum pump 53 evacuates the channel 1110a. In step STv, the coolant CL in the channel 1110a is substantially fully removed. In subsequent step STr, the pressure in the channel 1110a is returned to the initial pressure Pi. In step STr, the pressure in the channel 1110a may be returned to the initial pressure by supplying air from the cool air supply 52 to the channel 1110a. In step STr, the pressure in the channel 1110a may be set to an atmospheric pressure.

In one embodiment, the cycle including steps STa to STc may further include trapping the coolant CL with the trap 56 connected to the vacuum pump 53. The cycle may further include collecting the coolant CL with the collector described above.

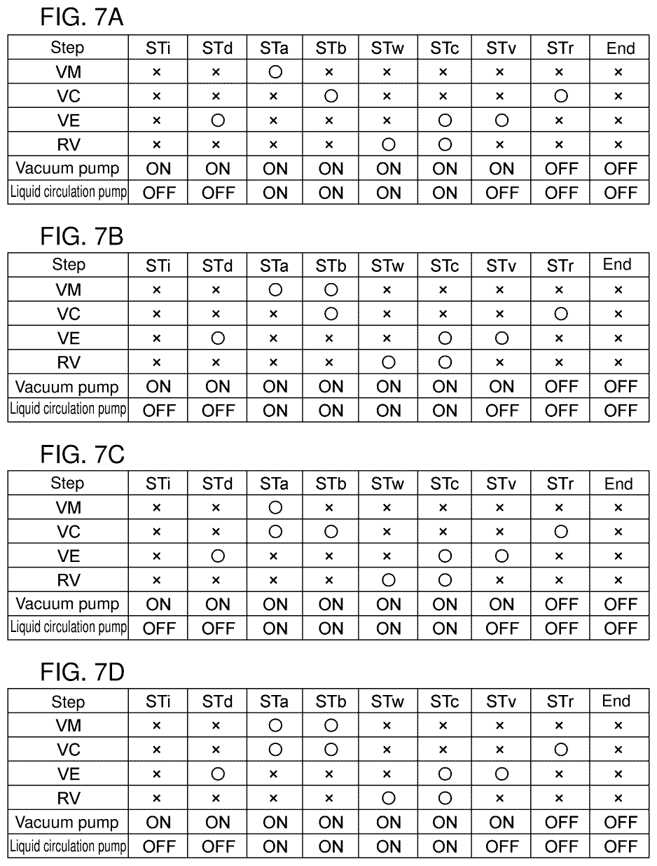

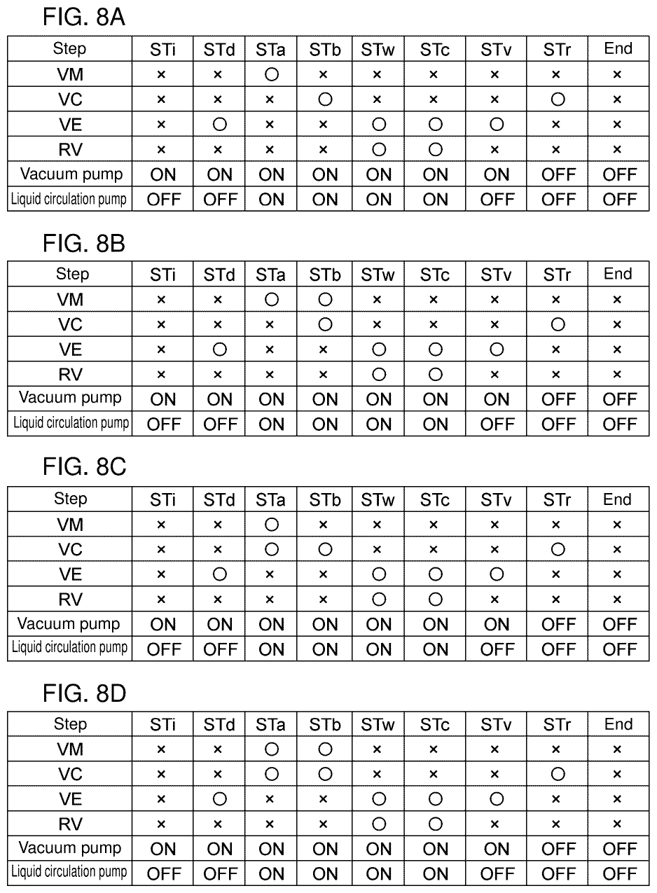

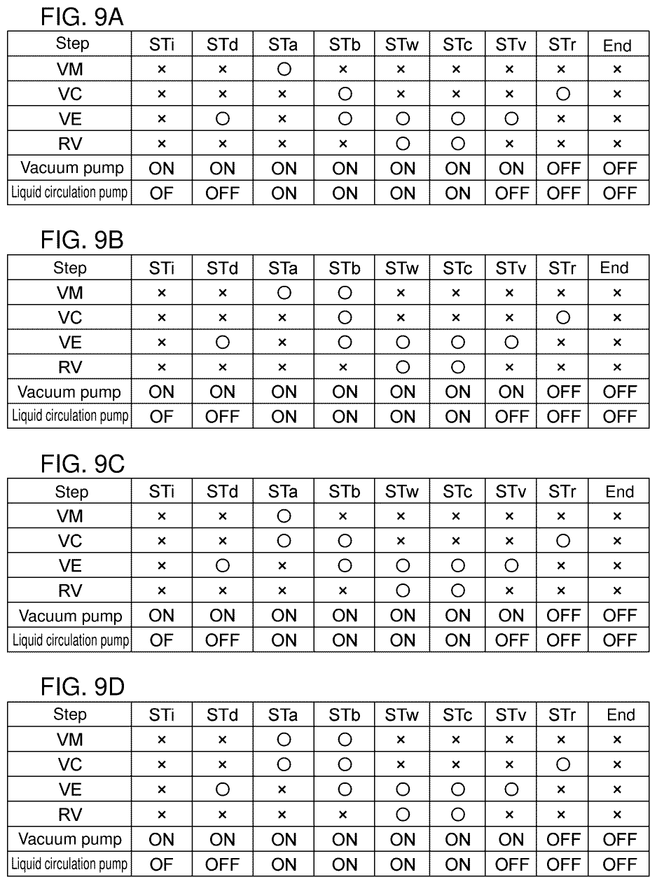

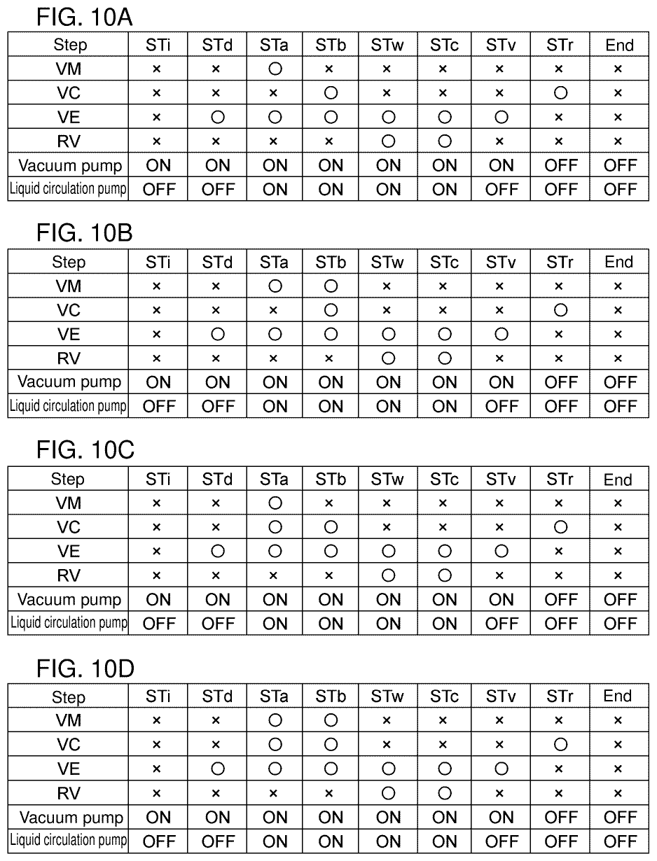

As described above, the components of the cooler 50 may be controlled by the controller 2 with the method MT. FIGS. 7A to 7D, 8A to 8D, 9A to 9D, and 10A to 10D are tables each showing example states of valves and pumps controlled with the cooling method according to the exemplary embodiment. The tables show the states of the valve VM, the valve VC, the valve VE, and the valve RV in each step. In the tables, the circle marks (o) and the cross marks (×) indicate the states of the valves. The circle mark indicates that the valve is open, and the cross mark indicates that the valve is closed. The tables also show the states of the vacuum pump 53 and the liquid circulation pump 58 in each step. In the tables, ON and OFF indicate the states of the pumps. ON indicates that the pump is operating, and OFF indicates that the pump is stopped. In each step in the method MT, the controller 2 may control the states of the valve VM, the valve VC, the valve VE, and the valve RV, and the states of the vacuum pump 53 and the liquid circulation pump 58 as shown in the tables.

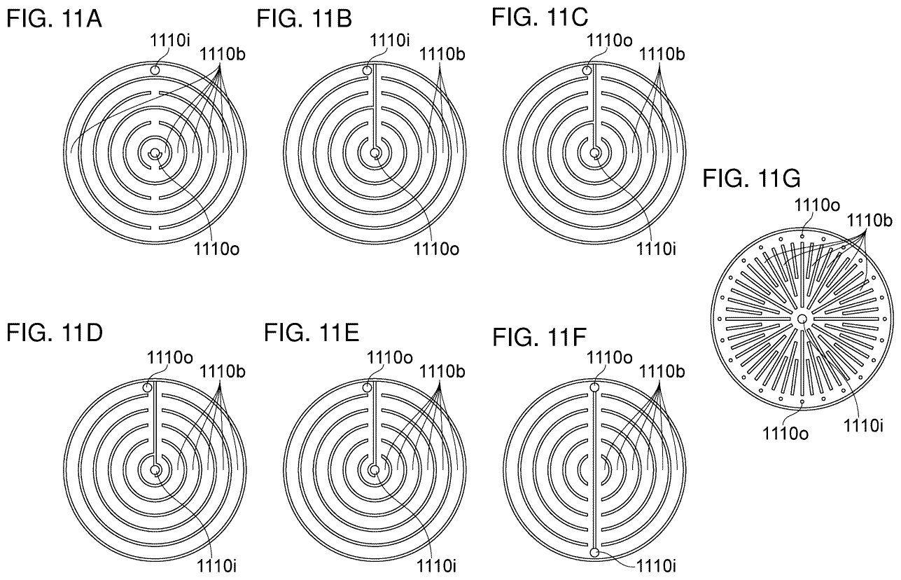

FIGS. 11A to 11F will now be referred to. FIGS. 11A to 11F are diagrams each showing an example channel in the base in the exemplary embodiment. The channel 1110a may be a single channel extending without branching between the inlet 1110i and the outlet 11100. In some embodiments, as shown in FIGS. 11A to 11F, the channel 1110a may include multiple branch channels 1110b branching from at least one inlet 1110i and merging into at least one outlet. In the examples in FIGS. 11A to 11F, the adsorption of the mist CLM onto the surface defining the channel 1110a and the separation of the coolant CL from the surface are facilitated.

In each of the examples in FIGS. 11A to 11F, the multiple branch channels 1110b branch from the single inlet 1110i and merge into the single outlet 11100. The branch channels 1110b extend circumferentially about the central axis of the base 1110. In the examples shown in FIGS. 11A and 11C to 11E, the single inlet 1110i is located at the center of the base 1110, and the single outlet 11100 is located at the outer edge of the base 1110. However, the single inlet 1110i may be located at the outer edge of the base 1110, and the single outlet 11100 may be located at the center of the base 1110 as in the example in FIG. 11B. In the example in FIG. 11F, the single inlet 1110i is located at the outer edge of the base 1110, and the single outlet 11100 is located opposite to the single outlet 11100 at the outer edge of the base 1110.

In the example in FIG. 11G, the single inlet 1110i is located at the center of the base 1110, and the multiple outlets 11100 are located at the outer edge of the base 1110. The branch channels 1110b branch from the single inlet 1110i and merge at the outer edge of the base 1110 including the multiple outlets 11100. The branch channels 1110b extend radially from the center of the base 1110 to the outer edge of the base 1110. The single outlet 11100 may be located at the center of the base 1110, and multiple inlets 1110i may be located at the outer edge of the base 1110.

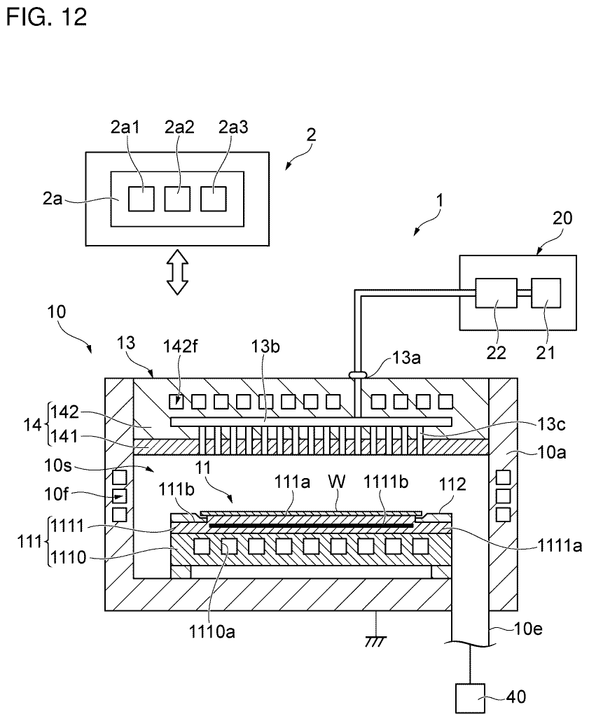

In the exemplary embodiment described above, the cooler 50 cools the substrate support 11 (or the base 1110 in the substrate support 11). In another exemplary embodiment, the cooler 50 may cool a member other than the substrate support 11. FIG. 12 will now be referred to. FIG. 12 is a diagram of a plasma processing apparatus according to a modification of the exemplary embodiment. In the plasma processing apparatus 1 shown in FIG. 12, the showerhead 13 includes the upper electrode 14 described above. The upper electrode 14 includes a channel 142f inside. The upper electrode 14 may include a ceiling plate 141 and a support 142. The ceiling plate 141 extends over the plasma processing space 10s to face the plasma processing space 10s. The ceiling plate 141 may be formed from, for example, a conductive material such as silicon. The support 142 supports the ceiling plate 141 in a detachable manner. The support 142 may be formed from a metal material such as aluminum. The support 142 may include the channel 142f and the gas-diffusion compartment 13b. The multiple gas guides 13c may be located inside the support 142 and the ceiling plate 141. In the plasma processing apparatus 1 shown in FIG. 12, the sidewall 10a of the chamber 10 may include a channel 10f inside.

In the plasma processing apparatus 1 shown in FIG. 12, one or more coolers 50 may be connected to one or more of the channels 10f, 142f, and 1110a. More specifically, the member cooled by the one or more coolers 50 may be one or more of the upper electrode 14 (or the support member 142), the sidewall 10a of the chamber 10, or the substrate support 11 (or the base 1110) in the plasma processing apparatus 1.

Although various exemplary embodiments have been described above, the embodiments are not restrictive, and various additions, omissions, substitutions, and changes may be made. The elements in the different embodiments may be combined to form another embodiment.

Various exemplary embodiments E1 to E13 included in the present disclosure will be described below.

### E1

A substrate processing apparatus, comprising:
a member including a channel inside, the channel having an inlet and an outlet;
a cooler configured to cool the member; and
a controller configured to control the cooler,
wherein the cooler includes
   a mist generator connected to the inlet and configured to generate a mist of a coolant,
   a cool air supply connected to the inlet, and
   a vacuum pump connected to the outlet, and
the controller causes the cooler to repeatedly perform processing including
   (a) supplying the mist from the mist generator to the channel, the channel being under a pressure reduced by the vacuum pump,
   (b) supplying cool air from the cool air supply to the channel, and
   (c) evacuating the channel with the vacuum pump.

### E2

The substrate processing apparatus according to E1, further comprising:
a trap connected to the outlet with the vacuum pump between the trap and the outlet, the trap being configured to trap the coolant; and
a collector connected between the trap and the mist generator and configured to collect and store the coolant.

### E3

The substrate processing apparatus according to E2, wherein
the collector includes
   a liquid circulation pump,
   a receiver including a tank to store the coolant, the receiver being connected between the trap and the liquid circulation pump, and
   a reservoir including another tank to store the coolant, the reservoir being connected between the liquid circulation pump and the mist generator.

### E4

The substrate processing apparatus according to any one of E1 to E3, further comprising:
a carrier gas supply connected to the inlet with the mist generator between the carrier gas supply and the inlet, the carrier gas supply being configured to supply a carrier gas to the channel together with the mist.

### E5

The substrate processing apparatus according to E4, wherein
the controller adjusts one or more of a plurality of control parameters including an amount of the mist generated by the mist generator, a temperature of the mist, a duration for which the mist is supplied to the channel, a flow rate of the carrier gas, a flow rate of the cool air supplied from the cool air supply, a temperature of the cool air, a duration for which the cool air is supplied, and a pumping speed of the vacuum pump.

### E6

The substrate processing apparatus according to any one of E1 to E5, wherein
the channel includes a plurality of branch channels branching from the inlet and merging into the outlet.

### E7

The substrate processing apparatus according to any one of E1 to E6, wherein the coolant is water, alcohol, ammonia, or a fluorine liquid.

### E8

The substrate processing apparatus according to any one of E1 to E7, further comprising:
a chamber; and
a substrate support in the chamber,
wherein the member is the substrate support.

### E9

The substrate processing apparatus according to any one of E1 to E7, further comprising:
a chamber;
a substrate support in the chamber; and
an upper electrode above the substrate support,
wherein the member is the upper electrode.

### E10

The substrate processing apparatus according to any one of E1 to E7, further comprising:
a chamber,
wherein the member is a sidewall of the chamber.

### E11

The substrate processing apparatus according to any one of E1 to E10, wherein
the substrate processing apparatus is a plasma processing apparatus.

### E12

A cooling method, comprising:
(a) supplying a mist of a coolant from a mist generator to a channel in a member, the channel being under a pressure reduced by a vacuum pump;
(b) supplying cool air from a cool air supply to the channel;
(c) evacuating the channel with the vacuum pump; and
(d) repeating a cycle including (a), (b), and (c).
E13

The cooling method according to E12, wherein
the cycle includes
trapping the coolant with a trap connected to the vacuum pump, and
collecting the coolant with a collector connected between the trap and the mist generator.

Various exemplary embodiments according to the present disclosure have been described by way of example, and various changes may be made without departing from the scope and spirit of the present disclosure. The exemplary embodiments described above are thus not restrictive, and the true scope and spirit of the present disclosure are defined by the appended claims.

### REFERENCE SIGNS LIST

1 Plasma processing apparatus

10 Chamber

11 Substrate support

1110 Base

1110a Channel

1110i Inlet

11100 Outlet

50 Cooler

51 Mist generator

52 Cool air supply

53 Vacuum pump

54 Carrier gas supply

56 Trap

57 Receiver

58 Liquid circulation pump

59 Reservoir

1. A substrate processing apparatus, comprising:
a member including a channel inside, the channel having an inlet and an outlet;
a cooler configured to cool the member; and
a controller configured to control the cooler,
wherein the cooler includes
a mist generator connected to the inlet and configured to generate a mist of a coolant,
a cool air supply connected to the inlet, and
a vacuum pump connected to the outlet, and
the controller is configured to control the cooler to repeatedly perform processing including supplying the mist from the mist generator to the channel, the channel being under a pressure reduced by the vacuum pump,
supplying cool air from the cool air supply to the channel, and
evacuating the channel with the vacuum pump.

2. The substrate processing apparatus according to claim 1, further comprising:
a trap connected to the outlet with the vacuum pump between the trap and the outlet, the trap being configured to trap the coolant; and
a collector connected between the trap and the mist generator and configured to collect and store the coolant.

3. The substrate processing apparatus according to claim 2, wherein
the collector includes
a liquid circulation pump,
a receiver including a tank to store the coolant, the receiver being connected between the trap and the liquid circulation pump, and
a reservoir including another tank configured to store the coolant, the reservoir being connected between the liquid circulation pump and the mist generator.

4. The substrate processing apparatus according to claim 1, further comprising:
a carrier gas supply connected to the inlet with the mist generator between the carrier gas supply and the inlet, the carrier gas supply being configured to supply a carrier gas to the channel together with the mist.

5. The substrate processing apparatus according to claim 4, wherein
the controller is configured to adjust one or more of a plurality of control parameters including: an amount of the mist generated by the mist generator, a temperature of the mist, a duration for which the mist is supplied to the channel, a flow rate of the carrier gas, a flow rate the cool air supplied from the cool air supply, a temperature of the cool air, a duration for which the cool air is supplied, and a pumping speed of the vacuum pump.

6. The substrate processing apparatus according to claim 1, wherein
the channel includes a plurality of branch channels branching from the inlet and merging into the outlet.

7. The substrate processing apparatus according to claim 1, wherein
the coolant is water, alcohol, ammonia, or a fluorine liquid.

8. The substrate processing apparatus according to claim 1, further comprising:
a chamber; and
a substrate support in the chamber,
wherein the member is the substrate support.

9. The substrate processing apparatus according to claim 1, further comprising:
a chamber;
a substrate support in the chamber; and
an upper electrode above the substrate support,
wherein the member is the upper electrode.

10. The substrate processing apparatus according to claim 1, further comprising:
a chamber,
wherein the member is a sidewall of the chamber.

11. The substrate processing apparatus according to claim 1, wherein
the substrate processing apparatus is a plasma processing apparatus.

12. A cooling method, comprising:
supplying a mist of a coolant from a mist generator to a channel in a member, the channel being under a pressure reduced by a vacuum pump;
supplying cool air from a cool air supply to the channel;
evacuating the channel with the vacuum pump; and
repeating a cycle including the supplying a mist, the supplying cool air, and the evacuating the channel.

13. The cooling method according to claim 12, wherein
the cycle includes
trapping the coolant with a trap connected to the vacuum pump, and
collecting the coolant with a collector connected between the trap and the mist generator.
